(19) United States
(12) Patent Application Publication
(10) Pub. No.: US 2009/0277782 A1
(43) Pub. Date: Nov. 12, 2009

(54) Silicon Oxynitride Coating Compositions

(75) Inventors: Nimel Theodore, Alexandria, VA (US); Brian C. Holloway, Danville, VA (US); Dennis M. Manos, Williamsburg, VA (US)

Correspondence Address: WILLIAM AND MARY TECHNOLOGY TRANSFER OFFICE, 402 JAMESTOWN RD, PO BO 8795, WILLIAMSBURG, VA, 23187-8795, US

(73) Assignee: COLLEGE OF WILLIAM AND MARY, Williamsburg, VA (US)

(21) Appl. No.: 12/507,460

(22) Filed: Jul. 22, 2009

Related U.S. Application Data
(62) Division of application No. 11/856,814, filed on Sep. 18, 2007.

(51) Int. Cl. C23C 14/34

(52) U.S. Cl. 204/192.15

(57) ABSTRACT

Silicon oxynitride compositions are described herein. These compositions are typically deposited onto substrates using a nitrogen plasma-based, reactive sputtering method. Depending on their composition, these coatings can be used for field emission suppression, dielectric applications, reflection control, and surface passivation.

### CROSS-REFERENCE TO RELATED APPLICATIONS

This application is a division (and claims the benefit of priority under 35 U.S.C. 120) of application Ser. No. 11/856,814, filed Sep. 18, 2007. The disclosure of the prior application is considered part of, and hereby incorporated by reference, in the disclosure of this application.

### STATEMENT REGARDING FEDERALLY SPONSORED RESEARCH AND DEVELOPMENT

This invention was made with government support under Grant No. DE-AC05-84ER-40150 awarded by the Department of Energy. The government has certain rights in the invention.

### FIELD OF INVENTION

This invention relates to silicon oxynitride coatings useful in both low voltage (e.g., semiconductors) and high voltage (e.g., field emission suppression) applications.

### BACKGROUND OF THE INVENTION

Although certain applications, like vacuum tubes, require materials that emit large currents at low voltages, other high voltage industries require the suppression of field emission. For example, the evolution of more powerful free-electron lasers (FEL) requires the development of brighter, higher-quality electron beams. Currently, field emission from support electrodes limits the operating voltages in DC-field photoelectron guns, which is problematic because operating at higher voltages would increase both the intensity and quality of the output electron beam by increasing the bunch charge and decreasing the divergence of the emitted electrons. Theodore et al. (“Nitrogen-implanted silicon oxynitride: a coating for suppressing field emission from stainless steel used in high-voltage applications” (2006) IEEE Transactions on Plasma Science, 34(4): p. 1074) have described a method to apply nitrogen-implanted silicon oxynitride coatings to flat stainless steel electrodes. This method drastically reduced the emitted electron current, but numerous arcs occurred during the coating process which severely damaged the electrode surface when this coating process was applied to three dimensional structures, in particular smooth, polished structures similar to those used in DC-field photoelectron guns. Thus, there remains a need for a processing technique that can uniformly deposit an arc-free, field suppression coating onto the large, 3-D, stainless steel electrodes.

Silicon dioxide is widely used in the semiconductor industry as an insulator due to its high thermal stability, low capacitance, low stress even with applied voltage, and compatibility with silicon wafer processing techniques. However, transistors that use silicon dioxide as a dielectric have a tendency to leak electrons when the transistor thickness is less than 130 nanometers. As silicon wafer processing has increasingly advanced into nanometer-scale dimensions, there is a need for an insulating dielectric that is better than silicon dioxide. Many dielectrics have been proposed, one of which is silicon oxynitride, which has the potential to cost-effectively fill this need because it is a stronger dielectric than silicon dioxide, and requires similar processing methods to those currently used with silicon dioxide.

Many methods have been used to create silicon oxynitride coatings, including chemical vapor deposition (CVD), plasma-enhanced CVD, rapid thermal processing, and remote plasma nitridation/oxidation. Each of these procedures may produce coatings with widely differing silicon, oxygen, nitrogen, and hydrogen compositions, bonding, and quality, which in turn determine the electrical properties of the layer. These processes can require a complex mixture of hazardous gases (ammonia, silane, nitric oxide, hydrogen, etc.) and/or high temperatures (450°-1000° C.) to achieve growth of the silicon oxynitride layer. There remains a need for a technique that deposits silicon oxynitride with high uniformity and purity, at low temperatures, and without using particularly hazardous gases.

### BRIEF SUMMARY OF THE INVENTION

Provided herein are silicon oxynitride coating compositions having a covalently bound nitrogen content of the silicon oxynitride between about 5% and 50%, and containing between 5% and 25% entrapped nitrogen gas (measured as a percentage of the total nitrogen content in the coating composition). In certain embodiments, the covalently bound nitrogen content of the silicon oxynitride is between about 15% and about 30%.

The compositions of the present invention are typically obtained using reactive sputtering methods for depositing silicon oxynitride on a substrate. For example, a representative composition of the present invention can be obtained in a reactive sputtering apparatus by evacuating a chamber containing the substrate, introducing nitrogen gas into the chamber, establishing a nitrogen plasma in the chamber through an antenna that is separated from the chamber by a quartz window; and sputtering the quartz window via electrostatic coupling of the nitrogen plasma and the antenna. Silicon and oxygen derived from the sputtering of the quartz window react with plasma-activated nitrogen gas, resulting in the deposition of silicon oxynitride onto the substrate.

The deposition rate and stoichiometry of the deposited silicon oxynitride can be controlled by varying the nitrogen plasma pressure, thereby allowing fine-tuning of the electrical properties of the coating. Furthermore, the nitrogen plasma pressure can be varied during the deposition process, allowing deposition of silicon oxynitride coatings having composition gradients, such as gradients of silicon oxynitride stoichiometry or gradients containing differing levels of entrapped nitrogen gas. The incident RF power can also be varied to change the silicon oxynitride deposition rate and change the amount of entrapped nitrogen.

The compositions of the present invention can be obtained using low-temperature deposition processes that require no external heat. The reduced temperature is potentially a significant advantage for structures or devices requiring multiple processing steps, but which may have a relatively low allowable total thermal budget. Such cases arise routinely in the production of semiconductor devices.

Nitrogen is the only requisite feed gas used in the plasma, thereby reducing the costs and hazards associated with hazardous gases commonly used in the prior art.

The compositions of the invention can be used to coat a wide variety of different substrate materials, including but not limited to aluminum, silicon, chromium, vanadium, titanium, zirconium, hafnium, niobium, molybdenum, tungsten, tantalum, rhenium, nickel, copper, silver, oxides and nitrides of the aforementioned materials, stainless steel, gallium arsenide, alumina, bisque alumina, quartz, borosilicate glass, plastics, ceramics, and kapton.

In one embodiment, the compositions of the invention are used as coatings to suppress field emission.

In another embodiment, the compositions of the invention are used as dielectrics in semiconductor devices such as transistors. One of the oft-cited disadvantages of using silicon oxynitride as a replacement for silicon dioxide is the high temperatures required, typically over 400° C., which can be incompatible with certain desirable photoresists or other processing materials or device layers. Herein, we describe silicon oxynitride coatings of high purity and uniformity that can be deposited onto substrates using low-temperature processing methods.

### BRIEF DESCRIPTION OF THE DRAWINGS

The summary above, and the following detailed description will be better understood in view of the drawings which depict details of preferred embodiments.

FIG. 1 shows a schematic diagram of exemplary equipment for depositing silicon oxynitride compositions of the present invention.

FIG. 2 shows a graph of silicon oxynitride deposition rate as a function of RF-power under the reactive sputtering experimental conditions described in Example 1.

FIG. 3 shows FTIR spectra of silicon samples coated with silicon oxynitride at varying RF-power under the reactive sputtering experimental conditions described in Example 1. Silicon dioxide and silicon nitride standards are shown at 1067 cm⁻¹ and 827 cm⁻¹, respectively.

FIG. 4 shows a graph of silicon oxynitride (FTIR) absorption peaks as a function of RF power under the reactive sputtering experimental conditions described in Example 1.

FIG. 5 shows a graph of silicon oxynitride deposition rate as a function of nitrogen pressure, with RF power held constant under the reactive sputtering experimental conditions of Example 2.

FIG. 6 shows FTIR spectra of silicon samples coated with silicon oxynitride at varying nitrogen pressure under the reactive sputtering experimental conditions described in Example 2.

FIG. 7 shows a graph of silicon oxynitride (FTIR) absorption peaks as a function of nitrogen pressure under the reactive sputtering experimental conditions described in Example 2.

FIG. 8 shows AES depth profile of reactively sputtered silicon oxynitride under the experimental conditions described in Example 3.

FIG. 9 shows elastic recoil detection analysis results of silicon oxynitride coatings deposited under the experimental conditions described in Example 3.

FIG. 10 shows the step profile of silicon oxynitride samples deposited under the experimental conditions described in Example 3.

FIG. 11 shows Rutherford Backscattering results on silicon oxynitride coatings deposited under the experimental conditions described in Example 3.

FIG. 12 shows a graph depicting the leakage current through a silicon oxynitride coating deposited on polished, 1.25″ diameter, stainless steel disks.

FIG. 13 shows field emission results from stainless steel electrodes coated with silicon oxynitride coating compositions of the present invention.

### DETAILED DESCRIPTION OF THE INVENTION

The present invention is directed to silicon oxynitride coatings useful in both low voltage (e.g., semiconductors) and high voltage (e.g., field emission suppression) applications.

As used herein, the term “covalently bound nitrogen content of the silicon oxynitride” refers to the percentage of the total Si—N and Si—O covalent bonds in a silicon oxynitride coating composition that are Si—N covalent bonds. This value can be determined indirectly using Fourier transform infrared absorption spectroscopy. In silicon oxynitride films, the dominant oxynitride peak shifts linearly between silicon dioxide and silicon nitride as the chemical bonding in the film changes; thus, the alloy composition of a given silicon oxynitride sample can be accurately determined by comparing the frequency of the oxynitride absorption band in a given sample with silicon dioxide and silicon nitride standards, which have peaks at 1067 cm⁻¹ for silicon dioxide and 827 cm⁻¹ for silicon nitride. For example, if a given silicon oxynitride sample had an oxynitride absorption peak at 1019 cm⁻¹, then the covalently bound nitrogen content of the silicon oxynitride sample would be calculated as 20%; i.e, (100×(1067−1019)/(1067−827)).

As used herein, the “ratio of entrapped nitrogen to total nitrogen within the coating composition” refers to the proportion of the total nitrogen in a silicon oxynitride coating that is entrapped nitrogen. It is the ratio of entrapped nitrogen to total nitrogen, wherein the total nitrogen content is the sum of the entrapped nitrogen and the nitrogen bonded to silicon.

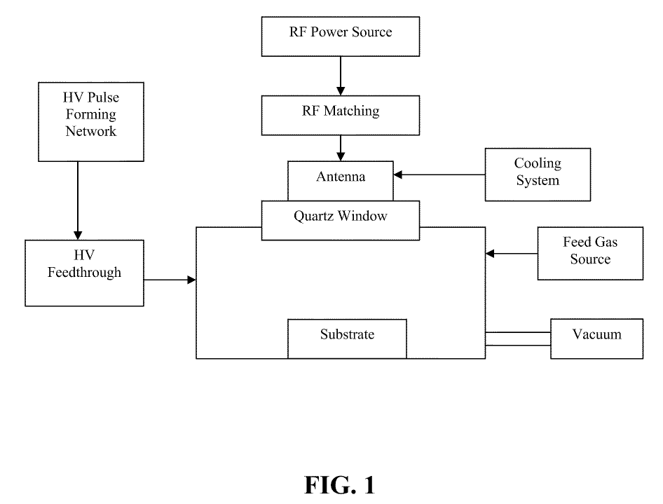

The compositions of the invention can be generated using suitable radio frequency plasma vapor deposition equipment. A schematic of equipment suitable to produce the compositions of the present invention is shown in FIG. 1. Radio frequency (RF) energy is introduced into a chamber 120 housing a substrate 200 that is to have silicon oxynitride deposited thereon. Such RF energy introduction can be achieved using an RF power source 102 that applies RF power to an antenna 108 (e.g., a planar coil antenna). Antenna 108 is disposed on one side of a quartz window 110 that forms a portion of a wall of chamber 120. A cooling system 106 can be coupled to antenna 108 to prevent heat damage to antenna 108. Gas used to a form a plasma inside of chamber 120 is introduced into chamber 120 from a controllable feed gas source 112. In the present invention, the feed gas is a “nitrogen gas” which can be pure nitrogen or a gas mixture that includes nitrogen as will be explained further below. Prior to introducing nitrogen gas into chamber 120, a vacuum 114 is used to evacuate chamber 120. Once chamber 120 is evacuated, nitrogen gas is introduced into chamber 120 from feed gas source 112. Antenna 108 is then powered by RF power source 102 with the resulting RF energy radiated by antenna 108 being introduced into chamber 120 through quartz window 110. The interaction of the RF energy with the nitrogen gas in chamber 120 generates a nitrogen plasma. RF matching 104 can be used to fine tune the RF power that is applied to antenna 108 for plasma generation. RF matching 104 can be realized by a capacitive matching circuit/network or by a circuit/network that alters the inductance of antenna 108.

Once the nitrogen plasma has been generated in chamber 120, quartz window 110 is sputtered into chamber 120. The present invention promotes such sputtering as a means for enabling silicon oxynitride deposition onto substrate 200. In general, the present invention achieves sputtering of quartz window 110 by electrostatically coupling antenna 108 to the nitrogen plasma generated in chamber 120. The nitrogen plasma both sputters and poisons the quartz window 110, releasing silicon, oxygen, and nitrogen from the window 110. The released silicon and oxygen can then react with nitrogen resulting in the deposition of silicon oxynitride onto the surface of substrate 200.

It has been found that the sputtering operation of the present invention can be controlled in order to control the sililcon oxynitride deposition rate and the stoichiometry of the deposited silicon oxynitride, i.e., the amount of entrapped nitrogen in the deposited silicon oxynitride. As a result, the final coating composition of silicon oxynitride on substrate 200 can have a composition gradient tailored for a specific application, e.g., field emission suppression, dielectric applications, reflection reduction and/or surface passivation. Such sputtering control can be achieved by controlling (e.g., varying) one or more of the pressure of the nitrogen plasma and the RF energy being introduced into chamber 120 during sputtering.

As mentioned above, the electrostatic coupling of the RF antenna to the plasma causes sputtering of the dielectric quartz window. The sputtered silicon and oxygen can deposit as silicon dioxide in an inert plasma (i.e., plasma using a non-reactive feed gas) or react with the activated nitrogen in the plasma to deposit silicon oxynitride. This deposition process can also be integrated with plasma immersion ion implantation to yield the simultaneous deposition and ion implantation of silicon oxynitride coatings.

The size of the chamber 120 can vary, and suitable sizes range from about 0.0001 cubic meters to 1 cubic meter. In representative embodiments described herein, the chamber used to deposit the silicon oxynitride coatings was about 0.12 cubic meters (4.3 cubic feet) in volume. Operating temperatures can be varied (e.g., via inclusion of heating and cooling elements in chamber 120) without departing from the scope of the present invention. In some useful embodiments, the operating temperature ranges from room temperature to a maximum of about 150° C.

In some embodiments, reactive sputtering can be supplemented with ion implantation to coat samples. The ion implantation is driven by the high voltage pulse forming network 130, which is coupled to the chamber 120 by a high voltage feedthrough 132. In one embodiment, a suitable high voltage pulse forming network includes a thyratron or other gas-tube or solid-state high-voltage switchgear, a high-voltage capacitor charge-storage bank, a capacitance charging supply, a transformer and inductor network for temporal pulse shaping and control, and associated triggering and timing circuitry. When utilizing the ion implantation mode, a Faraday shield (not shown in FIG. 1.) could be used to inhibit the sputtering of the quartz window by canceling the component of the electric field perpendicular to the window arising from oscillating voltages applied to antenna 108.

The plasma may be generated by nitrogen, as well as mixtures of nitrogen and another gas such as argon, oxygen, any other permanent or noble gases, or mixtures thereof. Additive or doping components from vaporized solids or liquids, emanating from sources such as nebulizers, atomizers, evaporators, sputter sources, or other such auxiliary means, may also be entrained into the plasma feed gases.

The reactive sputtering techniques described herein to deposit high-purity silicon oxynitride compositions of the present invention have many advantages. Importantly, large, three-dimensional samples can be successfully coated without arcs. This benefit is essential to producing a successful field emission suppression coating on large, contoured electrodes. The techniques described herein allow better control of the composition and the associated electrical properties of the silicon oxynitride coating. The source of silicon and oxygen in the coating is the sputtering of the fused quartz window. Since the sputtering rate of the window is RF-power and plasma-pressure dependent, varying these parameters changes both the deposition rate and composition of the resulting silicon oxynitride coatings. For example, one can easily deposit composition gradients of silicon oxynitride coatings simply by varying one of or both the parameters of RF-power and nitrogen plasma pressure.

The compositions of the present invention can be produced using low temperature surface processing techniques, and thus are particularly suitable for applications that have limited tolerance of higher temperatures.

In one embodiment of the invention, the compositions of the invention are used in photovoltaic cells as a coating that reduces reflection and provides good surface passivation. The stoichiometry of the silicon oxynitride coating can be tuned, and layers of silicon oxynitride of varying compositions within the coating can be deposited, all without stopping the deposition process or requiring new steps or set-up procedures. Accordingly, the anti-reflectance and surface passivation properties can be fine-tuned for performance without requiring any additional processing steps other than, for example, adjusting the nitrogen plasma pressure. Another advantage of the compositions of the present invention for photovoltaic applications are the low temperatures required, an important feature in preventing interdiffusion of the applied coating into the semiconductor solar cells.

### EXAMPLES

The examples that follow are intended in no way to limit the scope of this invention but are provided to illustrate representative embodiments of the present invention. Many other embodiments of this invention will be apparent to one skilled in the art.

General Procedure: The reactive sputtering coatings described in the following examples were deposited using reactive sputtering equipment having the configuration shown in FIG. 1 and further described as follows. The plasma system consisted of a cylindrical, 23″ ID, 18″ tall, stainless steel chamber capable of handling 300 mm Si wafers. The chamber contained several ports for feedthroughs, pressure gauges, gas inlets, and viewports. Two larger flanges (6″ and 10″ tube diameter) were machined into the side of the chamber. High vacuum was generated by a 1000 l/s magnetically-levitated turbo pump backed by a 16 cfm dry scroll pump, achieving an ultimate pressure of 6.6×10⁻⁷ Torr without a bake. A 200 amu Residual Gas Analyzer (RGA) was attached to the main chamber through an isolation manual gate valve. Since the vacuum pressure must be below 10⁻⁴ Torr for the RGA to function properly, another valve with a 1 mm throughput hole was used to reduce the gas load and a separate dry turbo pumping station was attached to the RGA for secondary pumping. A 2 kW RF power supply generated the plasma by inductively-coupling a planar coil antenna to the feed gas through a 1.25″ thick, 22.5″ diameter quartz window.

### Example 1

A set of experiments was performed using 7 mm×7 mm silicon samples that were all cut from the same wafer. Using the General Procedure described above for reactive sputtering, the nitrogen plasma pressure was fixed at 1.7 mTorr while the RF-power was incrementally adjusted. Four silicon samples and two “masked” silicon samples were then coated for 4 hours at each of the following RF power levels: 300 W, 450 W, 600 W, 750 W, and 1 kW incident power, with less than 25 W reflected power in all cases.

The two masked silicon samples were then analyzed using profilometry to measure the step height, or thickness of the coating. Each sample was analyzed at three different locations, and their corresponding thickness values were averaged. The deposition rate was then calculated by dividing the average thickness by the total process time, namely 240 min. The four other samples were analyzed using FTIR to determine how much Si—N content was present in the silicon oxynitride film. The corresponding oxynitride absorption peak was then averaged between the four samples. An uncoated silicon sample was used as the background to subtract any unwanted effects due to a thin oxide on the silicon itself. For reference, stoichiometric silicon dioxide and silicon nitride standards were also analyzed using FTIR.

Deposition Rate

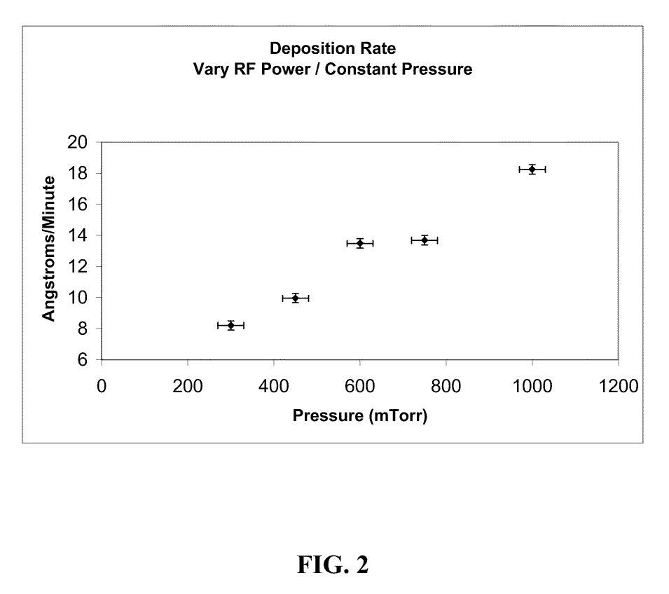

With other experimental values fixed, raising the incident RF-power increased the deposition rate of silicon oxynitride. The graph of the averaged step heights as a function of varying RF-power is shown in FIG. 2. The graph shows that increasing the RF-power linearly increased the deposition rate. At moderate powers, RF-power is known to vary linearly with plasma density in an inductively-coupled plasma. Thus, increasing the incident RF-power linearly increased the plasma density, thereby increasing the sputtering rate of the quartz window and the deposition rate on the sample.

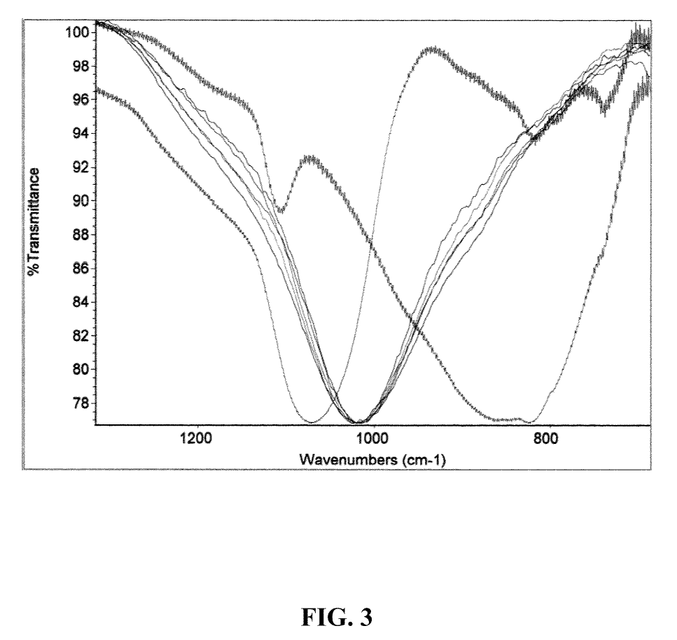

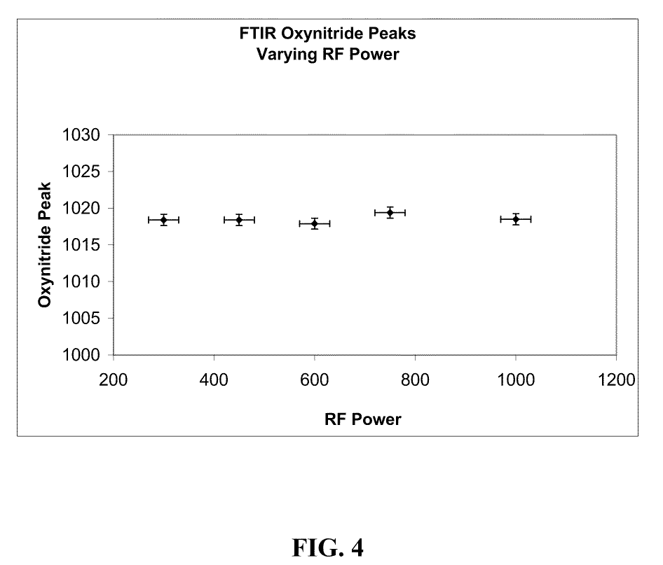

Chemical Composition. The FTIR spectra of the samples deposited with varied incident RF-power are shown in FIG. 3. The silicon oxynitride absorption peaks occur at around 1018 cm⁻¹, which correlates to 20%±0.5% Si—N content in the samples. The oxynitride absorption peak occurs closer to the silicon dioxide peak than the silicon nitride peak. Graphing the peak centers of the oxynitride absorption bands illustrates that varying the RF-power does not significantly change the covalent composition of the silicon oxynitride that is deposited. As shown in FIG. 4, all the peak centers are within 1.5 cm⁻¹ of each other, corresponding to a 0.625% difference in the amount of Si—N in the silicon oxynitride film.

X-ray photoelectron spectroscopy (“XPS”) was used to determine the chemical bonding of the deposited silicon oxynitride coatings. Surface scans were taken first, followed by 30 seconds of 5 keV Ar⁺ sputtering to remove approximately 30 Å from the top surface, and then the scans were taken again. Survey scans following the Ar⁺ sputter cleaning did not reveal any carbon on any of the samples; however, by the time the high-resolution scans for each atomic region were completed, about 2.5%-4% carbon was present in the spectra, likely arising from the adsorption of residual carbon species (predominantly CO, CO₂, and CH₄) in the vacuum environment.

Since all the XPS spectra possess residual surface carbon, charging effects can be accounted for by aligning all the C-1 s peaks in each spectrum. The deconvoluted spectra were compared with silicon dioxide and silicon nitride standards. As expected, the Si-2p peak shifts in the silicon oxynitride films more closely resembled silicon dioxide than silicon nitride, and the data suggest that the silicon oxynitrides formed by the reactive sputtering methods described herein were bonded the same way; that is, nitrogen and oxygen were only bonded to silicon, not to each other.

High-resolution scans show that there are two N-1s peaks present in the silicon oxynitride spectra. The extra peak is identified as entrapped nitrogen (N₂) in the silicon oxynitride films. By taking the peak areas of the unsputtered silicon oxynitride films, we can quantify the percentage of the nitrogen in the films that is trapped nitrogen. Accordingly, it was demonstrated that the ratio of entrapped nitrogen to total nitrogen within the coating composition can be adjusted by varying RF-power. In the present example, the maximum ratio of entrapped nitrogen to total nitrogen within the coating composition is about 17:100, obtained at the relatively low RF-power of 300 W, while the minimum ratio of entrapped nitrogen to total nitrogen in the coating composition was about 6:100, obtained at high RF-power of 1 kW.

### Example 2

A set of experiments was performed using 7 mm×7 mm silicon samples that were all cut from the same wafer. Using the General Procedure described above, the RF-power was fixed at 750 W incident power while the nitrogen plasma pressure was incrementally varied. The reflected RF-power was kept below 25 W. Six samples, comprising four silicon samples and two masked silicon samples, were coated for 4 hours at each of the following nitrogen pressures: 1 mTorr, 1.7 mTorr, 2.5 mTorr, 3.3 mTorr, 4 mTorr, and 5 mTorr. It should be noted that greater pressure ranges can be achieved with different vacuum pumps known in the art; for example, the 16 cfm scroll pump used in the present example could be replaced by a larger, oil-lubricated rotary vane pump, or the 1000 l/s maglev turbo pump used in the present example could be replaced with a smaller turbo pump.

The two masked silicon samples were then analyzed using profilometry to measure the step height, or thickness of the coating. Each sample was analyzed at three different locations, and their corresponding thickness values were averaged. The deposition rate was then calculated by dividing the average thickness by the total process time (240 minutes). The four other samples were analyzed using FTIR to determine how much Si—N content was present in the silicon oxynitride film. The corresponding oxynitride absorption peak was then averaged between the four samples. An uncoated silicon sample was used as the background to subtract any unwanted effects due to a thin oxide on the silicon itself. For reference, stoichiometric silicon dioxide and silicon nitride standards were also analyzed using FTIR.

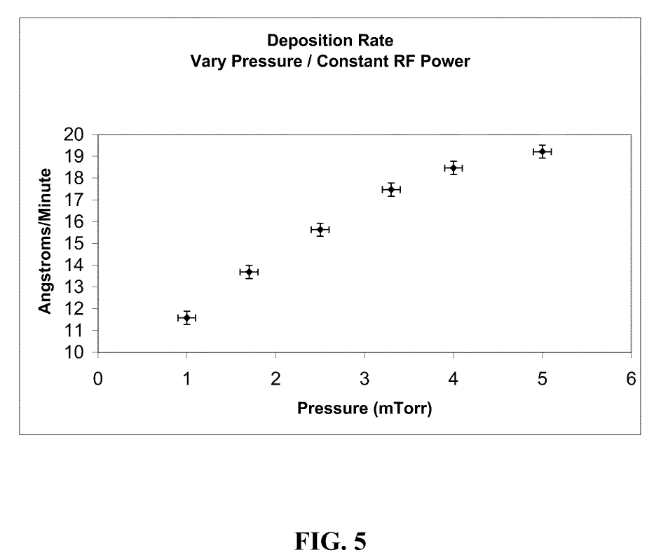

Deposition Rate. With other experimental values fixed, raising the nitrogen plasma pressure increases the deposition rate of silicon oxynitride. The graph of the averaged step heights with varying nitrogen pressure, shown in FIG. 5, illustrates that increasing the nitrogen pressure also increases the deposition rate (although it does not linearly increase the plasma density).

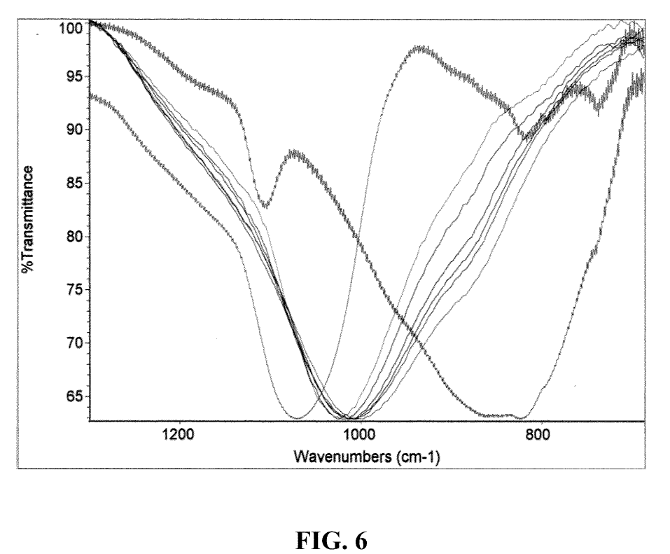

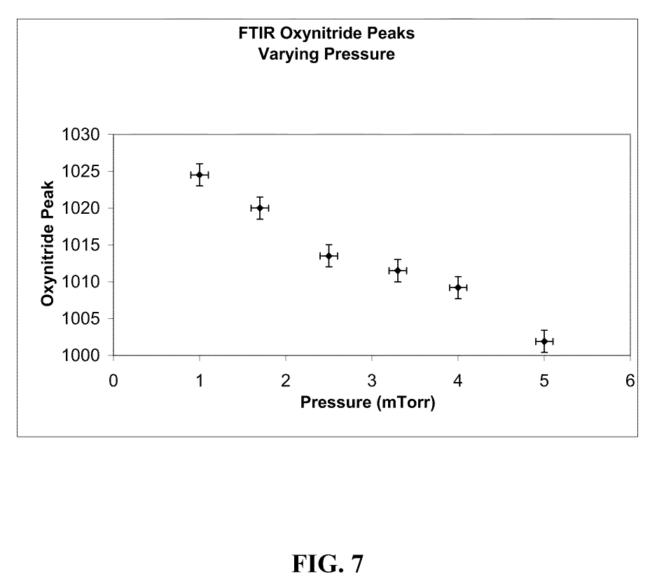

Chemical Composition. The FTIR spectra of the samples coated at various pressures are shown in FIG. 6. Small shifts in the oxynitride absorption band can be seen as pressure is increased. To better see this trend, a graph of the peak centers is shown in FIG. 7. As pressure increases, the location of the oxynitride absorption peak shifts to a lower wavenumber, indicating that as the pressure is raised, the amount of Si—N content in the silicon oxynitride also increases. Accordingly, by varying the nitrogen pressure within the experimental range described herein, the percentage of Si—N in the films can be controlled very accurately within the range of 15%-30%.

Following the method described in Example 1, high-resolution XPS was used to quantify the ratio of entrapped nitrogen to covalently bonded nitrogen within the coating composition. As nitrogen pressure was increased, the ratio of entrapped nitrogen to total nitrogen within the coating composition also increased. In the present example, the ratio of entrapped nitrogen to total nitrogen within the coating compositions reached its maximum value of 9:100 at the highest nitrogen pressure that was used (5 mtorr), and a minimum ratio of 6:100 was obtained at the lowest nitrogen pressure (1 mtorr) that was used.

### Example 3

Silicon oxynitride coatings were deposited onto 7 mm×7 mm silicon samples using the procedure of Example 1, with a fixed nitrogen pressure of 1.70 mtorr and 750 W incident RF power.

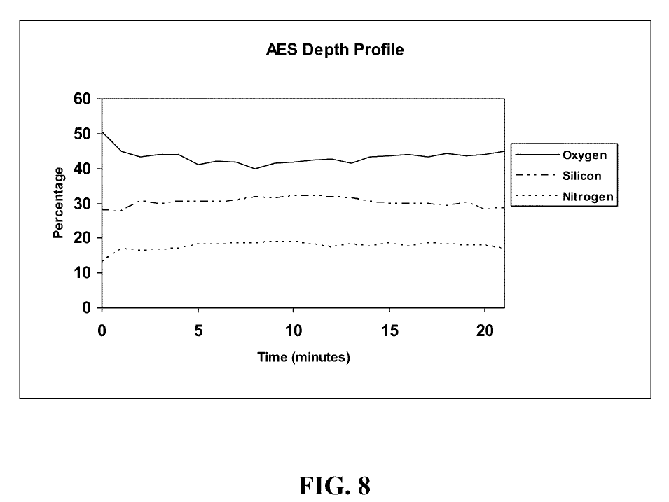

Atomic Composition—Auger Electron Spectroscopy. The atomic compositions of the silicon oxynitride layers created by the reactive sputtering deposition procedures were obtained using Auger Electron Spectroscopy (AES) with a cylindrical mirror electron energy analyzer having a fixed resolution of 0.6% of the peak energy. Depth profiles were obtained by rastering a 400-500 μm diameter, 3 keV argon ion beam to sputter a 2 mm by 2 mm surface area. The sputter rate was calibrated against that of silicon dioxide, and the relative sensitivity factor treated the silicon as an oxide. FIG. 8 shows the AES depth profile of the reactively sputtered silicon oxynitride films. A layer of silicon, oxygen, and nitrogen was deposited that is roughly 600 nm thick. The concentration of silicon was approximately 30% throughout the layer, and the concentration of nitrogen was approximately 18%.

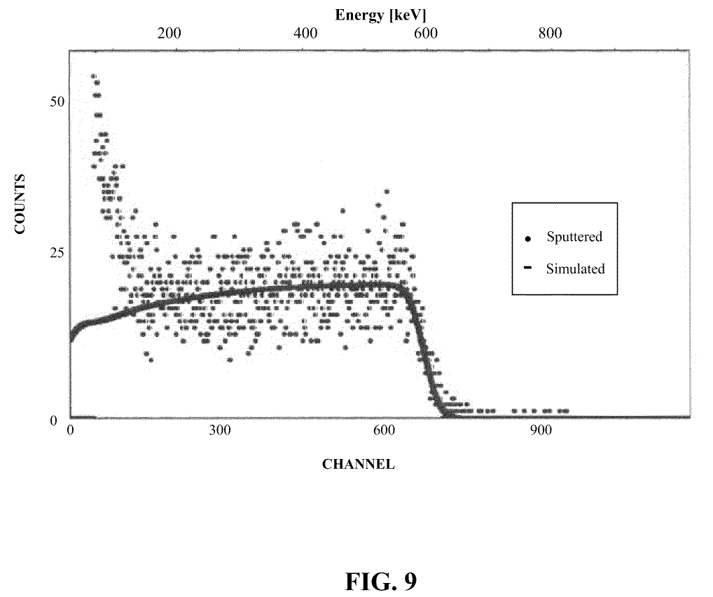

Hydrogen Composition—Elastic Recoil Detection Analysis. The atomic hydrogen-content of these layers was determined using Elastic Recoil Detection Analysis (ERDA). Helium ions (2.3 MeV) were bombarded into the coatings at a 75° incident angle (α), and the exit angle (β) was set at 60°. The detector had a fixed energy resolution of 25 keV. The ERDA results of the silicon oxynitride films are shown in FIG. 9. The reactively sputtered silicon oxynitride coating had approximately 1.5% hydrogen uniformly throughout the coating. Thus, despite no hydrogen-bearing gases being used in the deposition procedure, a small amount of hydrogen was still present in the film, possibly originating from the amorphous “quartz” window or from outgassed hydrogen-bearing species (H₂O, H₂, CH₄, etc.) from the stainless steel chamber, tubing, mounts, and electrodes. Though the inclusion of hydrogen in silicon oxynitride can cause electrical irregularities, the integrity of the coating was unaffected.

Density—Rutherford Backscattering and Profilometry. The density of the silicon oxynitride films was determined using profilometry Rutherford Backscattering (RBS). In RBS, 2.0 MeV He⁺ was incident on the film at an angle of 7° for a total Q of 40 μC; the scatter angle was 165°. The density of the film was then calculated by adding the total number of atoms per area and dividing by the film thickness determined by profilometry.

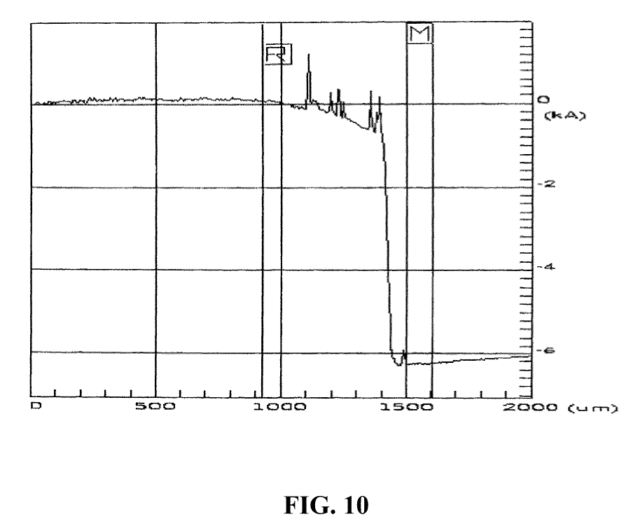

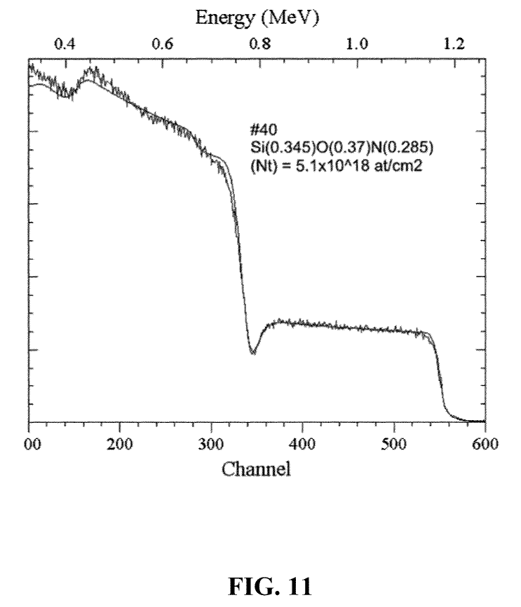

Using profilometry on masked silicon samples, the thickness of the coating was determined to be 650 nm±30 nm as seen in FIG. 10, while RBS (FIG. 11) was used to determine that the coating had a density of 5.1×10¹⁸±0.05 atoms/cm². These values correspond to a density of 7.83×10²² atoms/cm³.

### Example 4

To determine whether the composition and density of the silicon oxynitride films affected their electrical properties, we measured the resistivity and dielectric strength of silicon oxynitride compositions of the present invention that were reactively sputtered on polished, 1.25″ diameter, stainless steel disks. To make these measurements, a series of aluminum dots 0.75 mm in diameter were deposited onto the top surface of the coatings. A probe was attached to one dot while the back of the sample was held at ground. Subsequently, a DC voltage was applied to the probe (top surface of the sample). The voltage was increased and decreased sequentially, and the current was measured at the back of the sample. Since all the samples displayed ohmic behavior, the resistivity through the coating could be calculated from the equation derived from Ohm's law (J=E/ρ), where J is the current density (I/A), I is the measured leakage current, A is the area of the dots, E is the electric field (V/d), V is the applied voltage, and d is the thickness of the coating. The resistivity of the coating can then be calculated by taking the reciprocal of the slope of the resulting J vs. E plot.

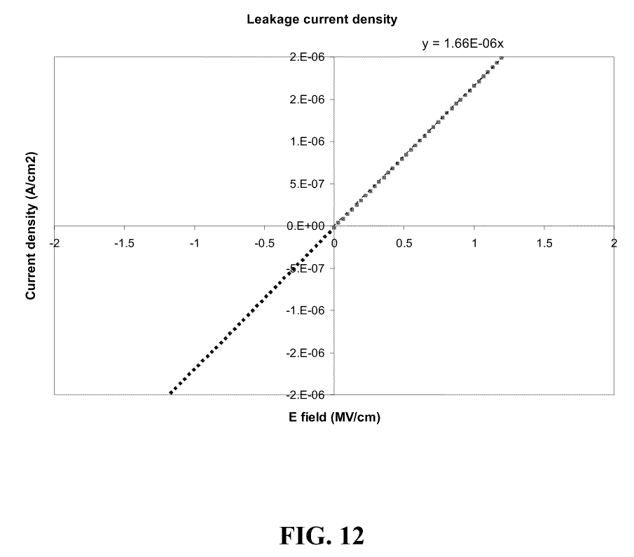

The data are presented in FIG. 12. Capacitance-voltage measurements were also taken at constant voltage, correcting for the leakage current. All samples exhibited resistivities around 10¹² Ω cm and had dielectric constants between 4.8-5.0±0.2.The result was compared with reference samples of silicon dioxide and silicon nitride, and it was determined that these silicon oxynitride films possessed between 13% and 30% nitride content. Although the range in these percentages is large, the calculated values agree with AES and FTIR results.

### Example 5

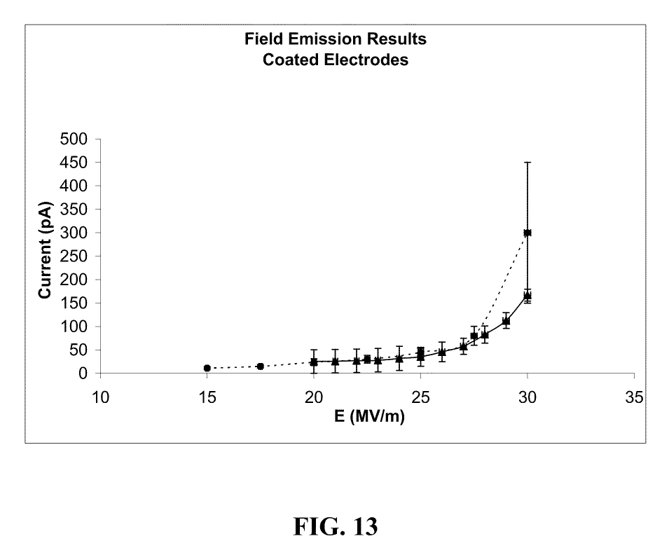

Field Emission Performance. The ability of silicon oxynitride compositions of the present invention to suppress field emission was studied. A flat, 6″ diameter, stainless steel electrode polished with 1 μm diamond paste was shown to emit 27 μA of electron current at electric field strengths of 15 MV/m. A 1 μm-thick, silicon oxynitride coating was deposited onto the stainless steel electrode using the General Procedure described above. At electric field strengths of 30 MV/m, the silicon oxynitride-coated stainless steel electrode emitted an average of 300 pA of electron current, as shown in FIG. 13, thereby demonstrating that the silicon oxynitride deposition compositions of the present invention adequately suppressed field emission from stainless steel electrodes.

### Example 6

A silicon oxynitride composition-gradient coating was deposited on a 6″ diameter stainless steel electrode by adjusting the nitrogen plasma pressure during the reactive sputtering process. Following the General Procedure described above, and using 1 kW RF power, the deposition process commenced with a nitrogen plasma pressure of 1.0 mtorr. After one hour, the nitrogen plasma pressure was increased by 0.5 mtorr to 1.5 mtorr, then held constant for one hour. Similarly, the nitrogen plasma pressure was incrementally increased by 0.5 mtorr at each successive hour, concluding after a total deposition time of ten hours and a final nitrogen plasma pressure of 5.5 mtorr.

### Example 7

The silicon oxynitride-coated stainless steel electrode of Example 6 was tested for its ability to suppress field emission. At electric field strengths of 31.25 MV/m (125 kV, 4 mm gap), the silicon oxynitride-gradient-coated stainless steel electrode exhibited <4 pA (detection limit) of electron current.

### Incorporation by Reference

All publications, patents, and patent applications cited herein are hereby expressly incorporated by reference in their entirety and for all purposes to the same extent as if each was so individually denoted.

### Equivalents

While specific embodiments of the subject invention have been discussed, the above specification is illustrative and not restrictive. Many variations of the invention will become apparent to those skilled in the art upon review of this specification. The full scope of the invention should be determined by reference to the claims, along with their full scope of equivalents, and the specification, along with such variations.

The articles “a” and “an” are used herein to refer to one or to more than one (i.e. to at least one) of the grammatical object of the article. By way of example, “an element” means one element or more than one element.

Any ranges cited herein are inclusive, e.g., “between about 15 percent and 100 percent” includes compositions containing 15% and 30%.

1.-7. (canceled)

8. A process for depositing silicon oxynitride on a substrate, comprising the steps of:
evacuating a chamber containing the substrate;
introducing nitrogen gas into the chamber;
establishing a nitrogen plasma in the chamber through an antenna that is separated from the chamber by a quartz window; and
sputtering said quartz window via electrostatic coupling of the nitrogen plasma and the antenna;
wherein silicon and oxygen from the sputtered quartz window react with said nitrogen gas to deposit silicon oxynitride onto the substrate.

9. The process of claim 8, wherein the substrate is selected from the group consisting of stainless steel, gallium arsenide, alumina, bisque alumina, quartz, borosilicate glass, plastics, ceramics, and kapton.

10. The process of claim 8, wherein the stoichiometry of the deposited silicon oxynitride coating is controlled by varying the pressure of the nitrogen plasma.

11. The process of claim 8, wherein the rate of deposition of silicon oxynitride is controlled by varying the incident RF power.

12. The process of claim 8, wherein the temperature at said substrate remains below 200° C. throughout the entire process.

13. The process of claim 8, wherein the substrate is a photovoltaic cell.

14. A method for suppressing field emission from a substrate comprising the steps of:
evacuating a chamber containing the substrate;
introducing nitrogen gas into the chamber;
establishing a nitrogen plasma in the chamber through an antenna that is separated from the chamber by a quartz window; and
sputtering said quartz window via electrostatic coupling of the nitrogen plasma and the antenna;
wherein silicon and oxygen from the sputtered quartz window react with said nitrogen gas to deposit silicon oxynitride onto the substrate; and
wherein a silicon oxynitride coating with a thickness of greater than 50 nm is deposited on the substrate.
